(19) United States
(12) Patent Application Publication
(10) Pub. No.: US 2026/0191104 A1
(43) Pub. Date: Jul. 2, 2026

(54) SEMICONDUCTOR PACKAGE COMPRISING STACKED CHIPS

(71) Applicant: SAMSUNG ELECTRONICS CO., LTD., Suwon-si (KR)

(72) Inventor: Hansae LIM, Suwon-si (KR)

(73) Assignee: SAMSUNG ELECTRONICS CO., LTD., Suwon-si (KR)

(21) Appl. No.: 19/385,756

(22) Filed: Nov. 11, 2025

(30) Foreign Application Priority Data
Dec. 27, 2024 (KR) 10-2024-0198039

(51) Int. Cl. H01L 25/065; H01L 23/00; H01L 23/373; H01L 23/498; H01L 23/538; H10B 80/00

(52) U.S. Cl. CPC H10W 90/00; H10B 80/00; H10W 40/253; H10W 70/611; H10W 70/65; H10W 90/701; H10W 72/07354; H10W 72/223; H10W 72/347; H10W 72/884; H10W 74/15; H10W 90/26; H10W 90/288; H10W 90/724; H10W 90/732; H10W 90/734; H10W 90/754

(57) ABSTRACT

Provided is a semiconductor package including a package substrate, first connection pads, and second connection pads, a first semiconductor chip on the package substrate, the first semiconductor chip including lower chip pads including a first group on a lower surface of the first semiconductor chip, a second semiconductor chip on the first semiconductor chip, the second semiconductor chip including upper chip pads including a first group disposed on an upper surface of the second semiconductor chip and a second group spaced apart from the first group, bumps connecting the first connection pads and the lower chip pads of the first group, and bonding wires connecting the second connection pads and the upper chip pads of the second group.

### CROSS-REFERENCE TO RELATED APPLICATION

This application claims priority to Korean Patent Application No. 10-2024-0198039 filed on Dec. 27, 2024, in the Korean Intellectual Property Office, the disclosure of which is incorporated herein by reference in its entirety.

### BACKGROUND

Embodiments of the present disclosure relate to a semiconductor package.

With the advancement of modern technology, systems satisfying high-speed data processing and power efficiency are required in various application fields such as artificial intelligence (AI), autonomous driving, and high-performance computing (HPC). Specifically, there is a task of minimizing power consumption and heat generation while processing large amounts of data in real time.

Accordingly, a semiconductor package is required to have high performance, large capacity, improved data processing efficiency, optimized power transmission, and improved thermal management performance. Additionally, optimization of channels to support data transmission and reception, improvement of power distribution networks (PDN), and maintenance of signal integrity are emerging as important factors in a semiconductor package.

### SUMMARY

One or more embodiments provide a semiconductor package simultaneously ensuring relatively high capacity and high performance within a single package. To this end, a structure is implemented that more effectively integrates a plurality of stacked semiconductor chips (e.g., memory chips) to maximize data processing performance and power efficiency.

According to an aspect of one or more embodiments, there is provided a semiconductor package, including a package substrate, a plurality of connection pads on a first surface of the package substrate, the plurality of connection pads including a first connection pad and a second connection pad, a first semiconductor chip on the plurality of connection pads, the first semiconductor chip including lower chip pads including a first group on a second surface of the first semiconductor chip and a second group spaced apart from the first group, and a lower insulating layer extending on a lower chip pad included in the second group and exposing at least a portion of a lower chip pad included in the first group, a second semiconductor chip on the first semiconductor chip, the second semiconductor chip including upper chip pads including a first group on a first surface of the second semiconductor chip and a second group spaced apart from the first group, and an upper insulating layer extending on an upper chip pad included in the first group and exposing at least a portion of an upper chip pad included in the second group, an interchip bonding layer between the first semiconductor chip and the second semiconductor chip, a connection bump connecting the first connection pad and the lower chip pad included in the first group, and a bonding wire connecting the second connection pad and the upper chip pad included in the second group.

According to another aspect of one or more embodiments, there is provided a semiconductor package, including a package substrate, a plurality of connection pads on a first surface of the package substrate, the plurality of connection pads including a first connection pad and a second connection pad, a first semiconductor chip on the plurality of connection pads, the first semiconductor chip including a first lower memory region configured to transmit data through at least one of a first channel and a second channel, and a second lower memory region configured to transmit data through at least one of the first channel and the second channel, a second semiconductor chip on the first semiconductor chip, the second semiconductor chip including a first upper memory region configured to transmit data through at least one of the first channel and the second channel, and a second upper memory region configured to transmit data through at least one of the first channel and the second channel, a connection bump connecting the first lower memory region and the second lower memory region to the first connection pad, and a bonding wire connecting the first upper memory region and the second upper memory region to the second connection pad.

According to still another aspect of one or more embodiments, there is provided a semiconductor package, including a package substrate including a first transmission path and a second transmission path, a first channel region on a first surface of the package substrate and connected to the first transmission path, a second channel region parallel to the first channel region and connected to the second transmission path, a first semiconductor chip including a first lower memory region and a second lower memory region, over the first semiconductor chip being on a portion of the first channel region and a portion of the second channel region, a second semiconductor chip including a first upper memory region and a second upper memory region, the second semiconductor chip on the first semiconductor chip, a connection bump connecting the first transmission path to the first lower memory region and the second lower memory region, and a bonding wire connecting the second transmission path to the first upper memory region and the second upper memory region.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a plan view of a semiconductor package according to one or more embodiments, and FIG. 1B is a bottom view of the semiconductor package according to one or more embodiments;

FIG. 2 is a cross-sectional view taken along line I-I′ of the semiconductor package of FIG. 1A;

FIG. 3 is a cross-sectional view taken along the line II-II′ of the semiconductor package of FIG. 1A;

FIG. 4 is a plan view of a package substrate included in a semiconductor package according to one or more embodiments;

FIG. 5A is a bottom view before a lower insulating layer of a semiconductor chip stack mounted on a semiconductor package according to one or more embodiments is disposed;

FIG. 5B is a bottom view of a semiconductor chip stack mounted on a semiconductor package according to one or more embodiments;

FIG. 5C is a bottom view of a semiconductor chip stack mounted on a semiconductor package of a modified embodiment;

FIG. 6A is a top view of a semiconductor chip stack mounted on a semiconductor package according to one or more embodiments before an upper insulating layer is disposed;

FIG. 6B is a top view of a semiconductor chip stack mounted on a semiconductor package according to one or more embodiments;

FIG. 6C is a top view of a semiconductor chip stack mounted on a semiconductor package according to one or more embodiments of modification;

FIG. 7 is a plan view illustrating a semiconductor package according to one or more embodiments;

FIG. 8 is a cross-sectional view taken along line III-III′ of FIG. 7;

FIG. 9 is a plan view illustrating a semiconductor package of a modified embodiment;

FIG. 10A is a plan view illustrating a semiconductor module according to one or more embodiments of the present disclosure, and FIG. 10B is a portion of FIG. 10A, and is a plan view of a front surface of the semiconductor package; and

FIGS. 11A, 11B, 11C, 11D, and 11E are views illustrating a manufacturing process of a semiconductor package according to one or more embodiments.

### DETAILED DESCRIPTION

Hereinafter, example embodiments of the present disclosure will be described with reference to the accompanying drawings. The same reference numerals denote the same elements in the drawings, and redundant descriptions on the same elements are omitted.

Embodiments described herein are example embodiments, and thus, the disclosure is not limited thereto.

Unless otherwise specified, in the present specification, it may be understood that the expressions such as “on,” “above,” “upper,” “below,” “beneath,” “lower,” and “side surface,” are merely indicated based on drawings, and may actually vary depending on the direction in which the components are disposed.

In order to distinguish various elements, steps and directions from each other, ordinal numbers such as “first,” “second,” “third,” etc. may be used as labels such as specific elements, steps, and directions, terms not described using “first,” “second,” etc. in the specification may still be referred to as “first” or “second” in the claim. Additionally, terms referred to as specific ordinal numbers (e.g., “first” in certain claims) may be described as different ordinal numbers (e.g., “second” in specifications or other claims) elsewhere.

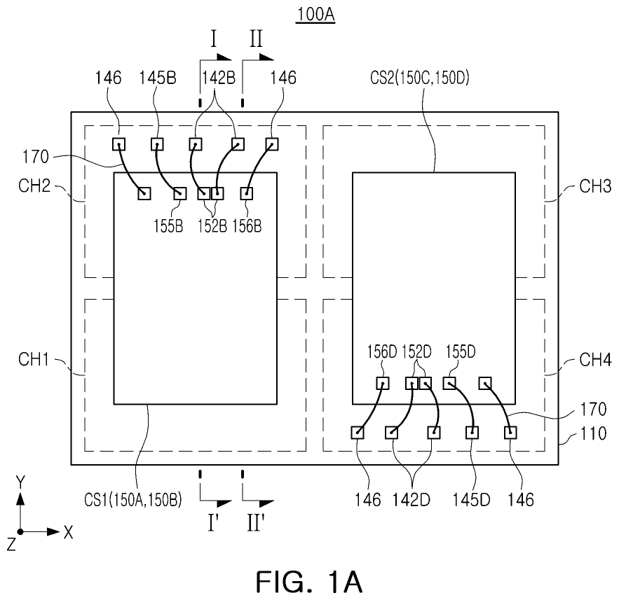

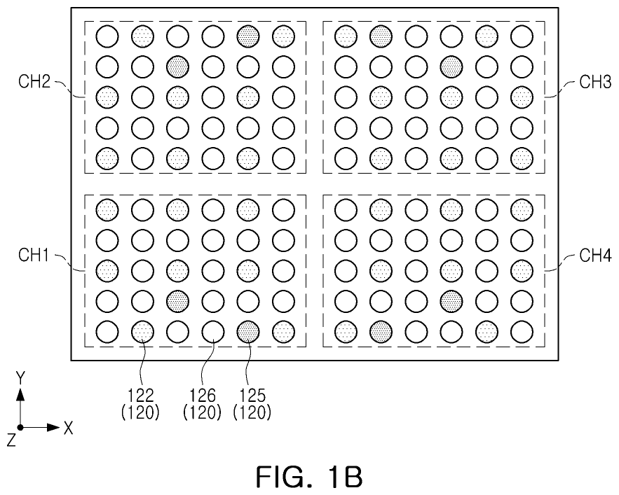

FIG. 1A is a plan view of a semiconductor package according to one or more embodiments, and FIG. 1B is a bottom view of the semiconductor package according to one or more embodiments.

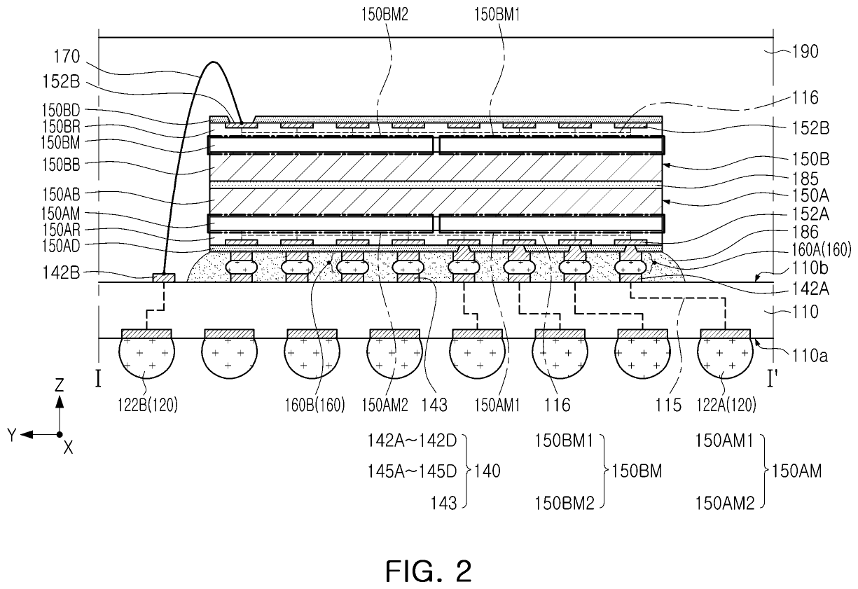

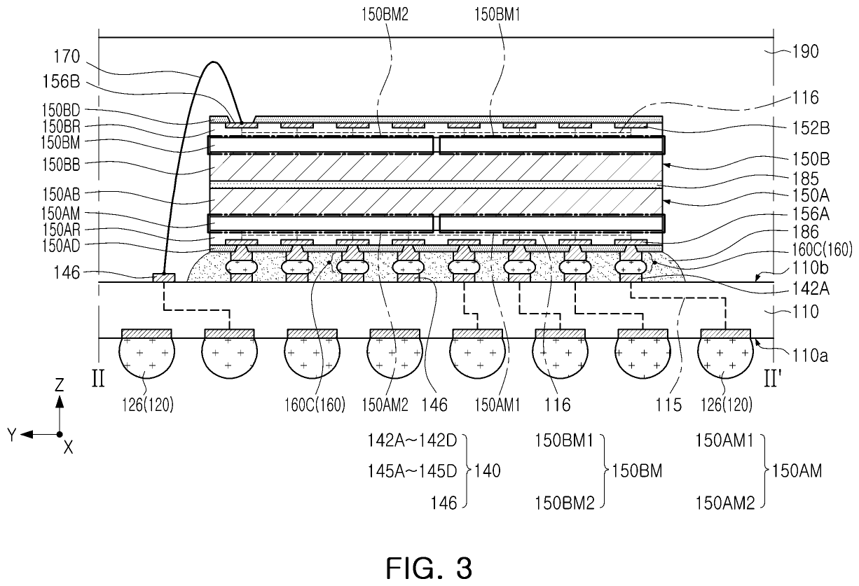

FIG. 2 is a cross-sectional view taken along line I-I′ of the semiconductor package of FIG. 1A, and FIG. 3 is a cross-sectional view taken along the line II-II′ of the semiconductor package of FIG. 1A.

As illustrated in FIG. 1A, a first chip stack CS1 and the second chip stack CS2 may be mounted together on a single package substrate 110. The first chip stack CS1 and the second chip stack CS2 may be arranged in a first direction (X-direction or Y-direction that are parallel to an upper surface of the first chip stack CS1) on a package substrate 110.

Referring to FIG. 1A and FIG. 2, the first chip stack CS1 may include a first semiconductor chip 150A flip-chip bonded on the package substrate 110, and a second semiconductor chip 150B disposed on the first semiconductor chip 150A and wire-bonded to the package substrate 110. Similarly, the second chip stack CS2 may include a third semiconductor chip 150C flip-chip bonded on the package substrate 110, and a fourth semiconductor chip 150D disposed on the third semiconductor chip 150C and wire-bonded to the package substrate 110.

Referring to FIG. 1A, a first channel region CH1 and a second channel region CH2 may be disposed adjacently to one of the two sides facing each other in the first direction (X-direction), and a third channel region CH3 and a fourth channel region CH4 may be disposed adjacently to the other side. The first chip stack CS1 may be disposed on portions of the first and second channel regions CH1 and CH2, and the second chip stack CS2 may be disposed on portions of the third and fourth channel regions CH3 and CH4. In one or more embodiments, the first and third channel regions CH1 and CH3 may be arranged in a first diagonal direction, and the second and fourth channel regions CH2 and CH4 may be arranged in a second diagonal direction, intersecting the first diagonal direction.

First to fourth semiconductor chips 150A, 150B, 150C and 150D may each include a memory chip having the same physical size and/or the same storage capacity. For example, the memory chip may be a dynamic random access memory (DRAM) chip. In one or more embodiments, each of the first and third semiconductor chips 150A and 150C may have a flip chip bonding structure having lower surface having chip pads (152A, 155A, and 152C, 155C) disposed identically to each other, and may be provided as a lower chip in each stack structure. Each of the second and fourth semiconductor chips 150B and 150D has a wire bonding structure having an upper surface with chip pads (152B, 155B and 152D, 155D) disposed identically to each other, and may be provided as an upper chip in each stack structure.

According to one or more embodiments, a chip stack having a lower chip of a flip chip bonding structure and an upper chip of a wire bonding structure may be configured. In this case, the first chip stack CS1 may be provided by disposing the chip stack over some regions of the first channel region CH1 and the second channel region CH2. The second chip stack CS2 may be provided by rotating the first chip stack CS1 by 180° and disposing the first chip stack CS1 over some regions of the third channel region CH3 and the fourth channel region CH4. The semiconductor chips 150A and 150C having the same structure may be alternately disposed in different chip stacks CS1 and CS2, such that an internal structure of each of the semiconductor chips 150A and 150C and an arrangement of connection pads 140 connected thereto may be symmetric (e.g., 180° rotational symmetry). The semiconductor chips 150B and 150D having the same structure may be alternately disposed in different chip stacks CS1 and CS2, such that an internal structure of each of the semiconductor chips 150B and 150CD and an arrangement of the connection pads 140 connected thereto may be symmetric (e.g., 180° rotational symmetry). Accordingly, the description of the first chip stack CS1 may also be applied to the second chip stack CS2. For example, the description associated with the first channel and the first semiconductor chip 150A may be applied to the description associated with the third channel and the third semiconductor chip 150C, and the description associated with the second channel and the second semiconductor chip 150B may also be applied to the description associated with the fourth channel and the fourth semiconductor chip 150D. Since the first chip stack CS1 and the second chip stack CS2 may be configured identically, the following description will be made focusing on the components of the first chip stack CS1.

The first chip stack CS1 may be disposed in the middle of the first channel region CH1 and the second channel region CH2. Areas of the first chip stack CS1 overlapping the first channel region CH1 and the second channel region CH2 may be substantially the same. Since the first chip stack CS1 is formed by bonding the first semiconductor chip 150A and the second semiconductor chip 150B, an area (e.g. a size) of a region in which the first channel region CH1 and the first semiconductor chip 150A overlap each other may be substantially the same as an area (e.g. a size) of a region in which the second channel region CH2 and the second semiconductor chip 150B overlap each other. For example, a first lower memory region 150AM1 and a first upper memory region 150BM1 may be disposed on the first channel region CH1, and a second lower memory region 150AM2 and a second upper memory region 150BM2 may be disposed on the second channel region CH2.

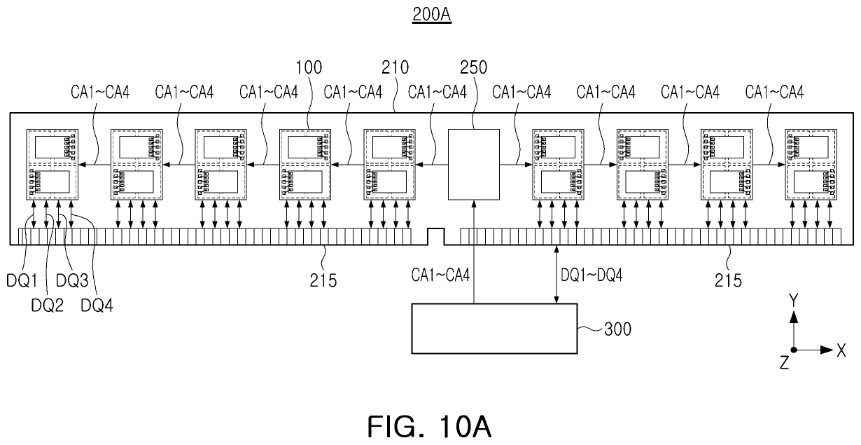

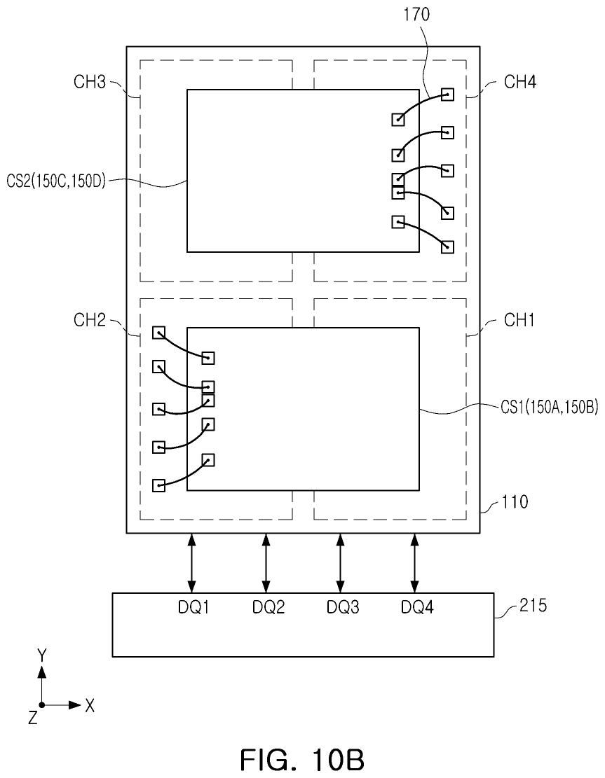

Referring to FIG. 1B, a plurality of connection terminals 120 may be arranged in a two-dimensional array structure in the first direction (X-direction) and a second direction (Y-direction), perpendicular to the first direction (X-direction), on the lower surface 110a of the package substrate 110. The plurality of connection terminals 120 may be mounted on a plurality of ball lands on a lower surface 110a of the package substrate 110, respectively. For example, the plurality of connection terminals 120 may include solder balls. The plurality of connection terminals 120 may be provided as external contact points for connection with an external device (see 300 of FIG. 10A).

The package substrate 110 adopted in one or more embodiments may have an arrangement of connection terminals, similarly to the JEDEC Ball Map standard. A plurality of connection terminals 120 may be arranged on a lower surface of the package substrate 110, and the plurality of connection terminals 120 may be arranged in a two-dimensional array structure in the first direction (X-direction) and the second direction (Y-direction), perpendicular to the first direction (X-direction) on the lower surface 110a of the package substrate 110. The plurality of connection terminals 120 may include DQ terminals 122 divided and disposed in the first channel region to the fourth channel region CH1, CH2, CH3 and CH4, CA terminals 125 divided and disposed in in the first channel region to the fourth channel region CH1, CH2, CH3 and CH4, and may include various power/ground terminals 126.

The power/ground terminals 126 associated with power supply may include, for example, various power supply terminals (e.g., VCC, VDD and VPP) and ground terminals (e.g., VSS). The power/ground terminals 126 may be distributed to each channel regions CH1, CH2, CH3 and CH4, and power supply terminals and connection terminals may be disposed between the DQ terminals 122 or between the CA terminals 125.

Referring to FIG. 1A and FIG. 2, a semiconductor package 100A according to one or more embodiments may include a package substrate 110, a first chip stack CS1 of a first semiconductor chip 150A and a second semiconductor chip 150B on a region of the package substrate 110, a second chip stack CS2 of a third semiconductor chip 150C and a fourth semiconductor chip 150D on another region of the package substrate 110, and a molding member 190 covering the first and second chip stacks CS1 and CS2 on the package substrate 110.

Referring to FIG. 2, the first chip stack CS1 may include a first semiconductor chip 150A flip-chip bonded on a package substrate 110, and a second semiconductor chip 150B disposed on the first semiconductor chip 150A and wire-bonded to the package substrate 110. Here, an interchip bonding layer 185 may be disposed between each of the first and second semiconductor chips 150A and 150B.

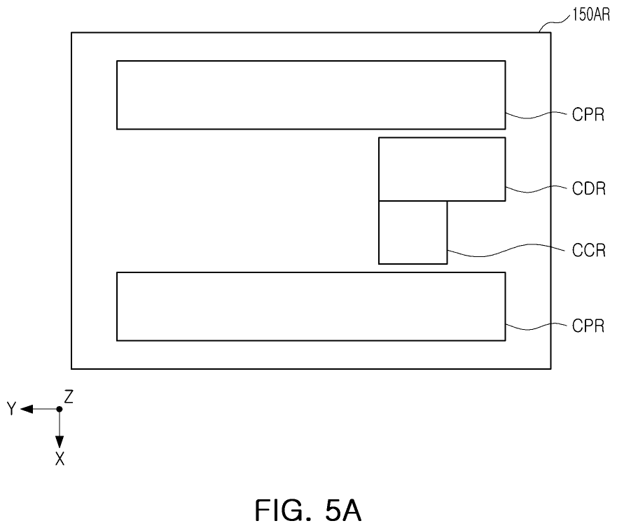

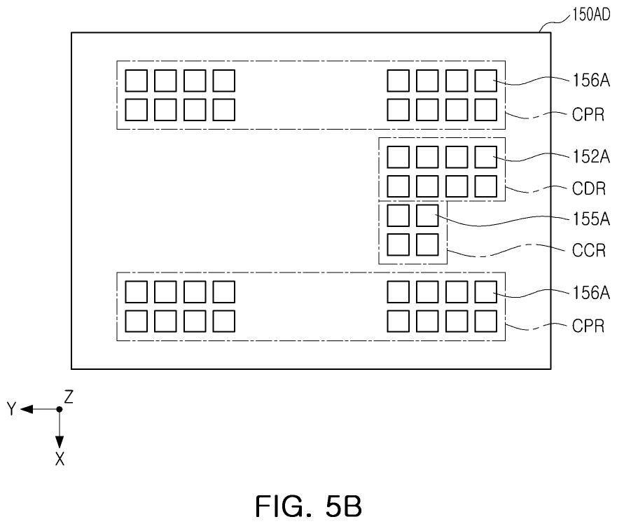

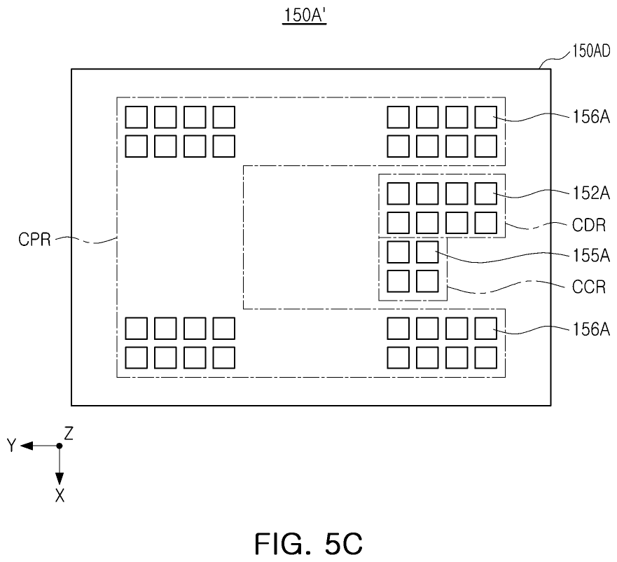

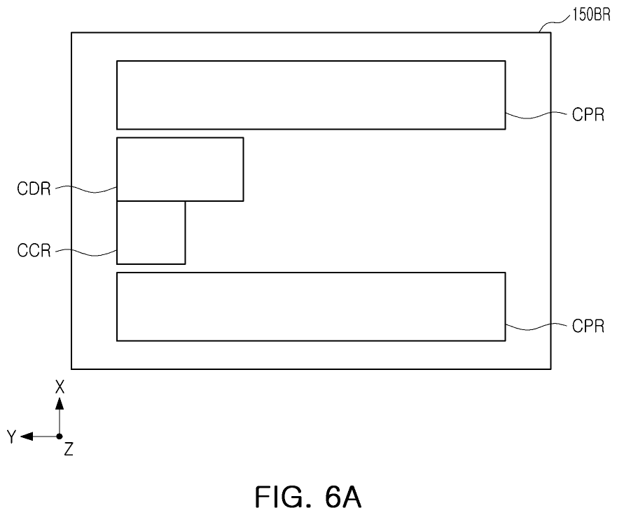

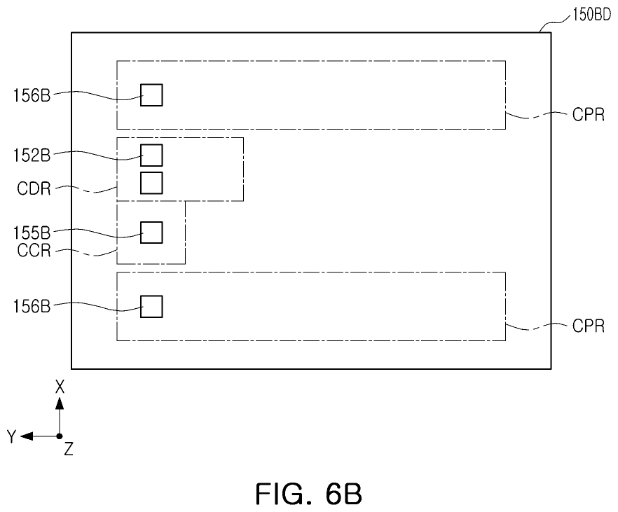

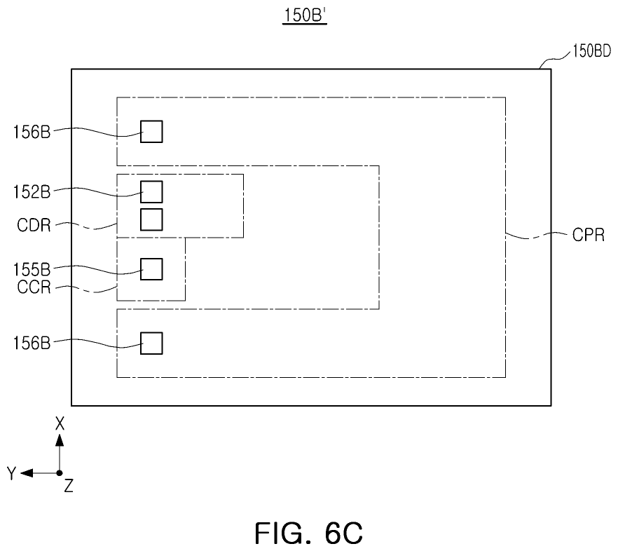

In one or more embodiments, each of the first to fourth semiconductor chips 150A, 150B, 150C and 150D may be configured to transmit or receive a data signal to or from an external controller through an independent channel. This will be described in detail later with reference to FIGS. 5A to 6C.

The package substrate 110 may be a printed circuit board (PCB) having a lower surface 110a and an upper surface 110b opposite to the lower surface. A plurality of connection terminals 120 may be arranged on the lower surface 110a of the package substrate 110, and a plurality of connection pads 140 may be disposed on an upper surface 110b of the package substrate 110. The plurality of connection pads 140 may be respectively connected to the plurality of connection terminals 120 by interconnection circuits 115 of the package substrate 110, and may be respectively disposed in desired bonding regions for the first to fourth semiconductor chips 150A, 150B, 150C and 150D. The interconnection circuits 115 may include interconnection patterns on each insulating layer of the package substrate 110 and vias connecting the interconnection patterns.

The package substrate may include first to fourth data transmission paths configured to transmit and receive a data signal of first to fourth channels respectively provided to first to fourth semiconductor chips 150A, 150B, 150C and 150D. The first to fourth data transmission paths may include interconnection circuits 115.

The plurality of connection terminals 120 may be arranged so as to provide a path of a signal determined according to a predetermined standard (e.g., JEDEC Ball Map standard) from an external device. The external device may control data reading from the first to fourth semiconductor chips 150A, 150B, 150C and 150D and data writing to the first to fourth semiconductor chips 150A, 150B, 150C and 150D through the plurality of connection terminals 120. Data signals may include data signals such as DQ, DQS and DQSB, and the control signal may be referred to as a command and address signal (CA) other than the data signal. For example, the command and address signal (C/A) may include CMD, ADDR, and CTRL.

The data signals may be divided into four channels and may be transmitted to each of the first to fourth semiconductor chips 150A, 150B, 150C and 150D, and as illustrated in FIG. 1A, an arrangement region of the DQ terminals 122 associated with the data signals (DQ1, DQ2, DQ3, DQ4 of FIG. 10A) of each channel may be divided into four channel regions CH1, CH2, CH3 and CH4 in a plane. For example, first DQ connection pads 142A may be configured to transmit and receive a data signal through the first channel, and a second DQ connection pad 142B may be configured to transmit and receive a data signal through the second channel.

The first to fourth channel regions CH1, CH2, CH3 and CH4 may be provided as transmission paths for data signals (DQ1, DQ2, DQ3, DQ4 in FIG. 10A) of the first to fourth channels provided to the first to fourth semiconductor chips 150A, 150B, 150C and 150D, respectively.

The command/address signal (C/A) may be transmitted to each of the first to fourth semiconductor chips 150A, 150B, 150C and 150D in four channels, similar to the data signals, and as illustrated in FIG. 2, an arrangement region of CA terminals 125C1, 125C2, 125C3 and 125C4 associated with the command/address signal (CA1, CA2, CA3, CA4 of FIG. 10A) of each channel may be divided into four channel regions CH1, CH2, CH3 and CH4 on a plane. The first to fourth channel regions CH1, CH2, CH3 and CH4 may be provided as transmission paths of command/address signals (CA1, CA2, CA3, CA4 of FIG. 10A) of the first to fourth channels, which are respectively provided to the first to fourth semiconductor chips 150A, 150B, 150C and 150D.

Referring to FIG. 1B and FIG. 3, power/ground terminals 126 associated with power supply may include, for example, various power supply terminals (e.g., VCC, VDD and VPP) and ground terminals (e.g., VSS). The power/ground terminals 126 may be distributed to each channel region CH1, CH2, CH3 and CH4, and the power supply terminals and connection terminals may be disposed between the DQ terminals 122 or between the CA terminals 125.

In one or more embodiments, first DQ connection pads 142A, second DQ connection pads 142B, third DQ connection pads 142C and fourth DQ connection pads 142D may be disposed on the first to fourth channel regions CH1, CH2, CH3 and CH4, respectively. Specifically, each of the first DQ connection pads 142A may be disposed within a mounting region of the first semiconductor chip 150A, and may be connected to the first DQ chip pads 152A, respectively. Similarly, each of the second DQ connection pads 142B may be disposed within a mounting region of the second semiconductor chip 150B, and may be connected to the second DQ chip pads 152B, respectively.

Additionally, the first CA terminals 125C1 may be connected to first CA connection pads 145A via an interconnection circuit 115C1, respectively. The first CA connection pads 145A may be disposed so as to be flip-chip bonded in a region in which the first semiconductor chip 150A is mounted. Additionally, second CA connection pads 145B may be disposed adjacently to the second semiconductor chip 150B in a region adjacent to and around one side of the first and second semiconductor chips 150A and 150B. The second CA connection pads 145B may be disposed so as to be wire-bonded around a region in which the second semiconductor chip 150A is mounted.

The first CA connection pad 145A and a third CA connection pad 145C may be disposed within the mounting regions of the first and third semiconductor chips 150A and 150C, respectively, and may be connected to the first and third CA chip pads 155A and 155C, respectively. In one or more embodiments, power/ground connection pads 146 may be disposed over an entire upper surface of the package substrate 110, i.e., the first to fourth channel regions CH1, CH2, CH3 and CH4, respectively. Some of the power/ground connection pads 146 may be disposed within the mounting regions of the first and third semiconductor chips 150A and 150B, respectively, and may be connected to first and third power/ground chip pads 156A and 156B, respectively.

Chip pads of the first and third semiconductor chips 150A and 150C, which are flip-chip bonded, may be connected to the first and third DQ connection pads 142A and 142C, the first and third CA connection pads 145A and 145C, and some power/ground connection pads 146 by conductive bumps 160, such as micro bumps.

Referring to FIGS. 2 and 3, the first semiconductor chip 150A may include a semiconductor base 150AB, a lower memory region 150AM, a lower circuit layer 150AR, a plurality of lower chip pads 152A, 155A and 156A, and a lower insulating layer 150AD.

The semiconductor base 150AB may be a semiconductor wafer substrate. For example, the semiconductor base 150AB may be a semiconductor wafer including a semiconductor element such as, for example, silicon, germanium, or a compound semiconductor such as silicon carbide (SiC), gallium arsenide (GaAs), indium arsenide (InAs), and indium phosphide (InP).

The lower memory region 150AM may include a first lower memory region 150AM1 and a second lower memory region 150AM2. The first and second lower memory regions 150AM1 and 150AM2 may include various types of material layers included in integrated circuits or memory components. The first and second lower memory regions 150AM1 and 150AM2 may be device layers including elements included in integrated circuits or memory components. Electronic elements included in the memory component may be integrated in the first and second lower memory regions 150AM1 and 150AM2. The electronic elements may include transistor or capacitor structures.

The first lower memory region 150AM1 may be configured to transmit data through at least one channel. The second lower memory region 150AM2 may be configured to transmit data through at least one channel. For example, the first and second lower memory regions 150AM1 and 150AM2 may be configured to transmit data through at least one of the first channel or the second channel region CH2. For example, the first lower memory region 150AM1 may be connected to the first DQ connection pads 142A and may be configured to transmit and receive a data signal through the first channel, and the second lower memory region 150AM2 may be connected to the second DQ connection pad 142B and may be configured to transmit and receive a data signal through the second channel.

Referring to FIG. 2, the second lower memory region 150AM2 may not be connected to and spaced apart from the second DQ connection pad, and may be electrically connected to the first DQ connection pad 142A along the interconnection circuit 115, and may be configured to transmit and receive a data signal through the first channel. Unlike a related art in which information of a memory region may be read by connecting the second lower memory region 150AM2 to the second DQ connection pad 142B and transmitting and receiving two data input/output signals using one semiconductor chip, the first semiconductor chip 150A according to one or more embodiments may be configured to transmit and receive a data signal through the first channel to the first lower memory region 150AM1 and the second lower memory region 150AM2.

The memory region 150AM of the first semiconductor chip 150A may transmit data through at least one channel. However, embodiments are not limited thereto and, the data signal of one channel may be transmitted and received for an entire memory region of one semiconductor chip. Accordingly, the data memory capacity per channel may be increased by enabling one semiconductor chip to transmit and receive only data of a single channel. Additionally, since two or more data signals are not transmitted and received from one semiconductor chip, the DQ chip pads may be concentrated on one channel.

For example, according to one or more embodiments, the first lower memory region 150AM1 and the second lower memory region 150AM2 may be configured to transmit and receive data of the first channel through the lower DQ chip pads 152A. Accordingly, the first semiconductor chip 150A may transmit and receive only data of the first channel, thereby increasing the data transmission and reception capacity per semiconductor chip. Additionally, the first DQ chip pads 152A may be concentrated on the first channel. Accordingly, heat generation may occur on the first channel region CH1 and not on the entire semiconductor chip.

A plurality of lower chip pads 152A, 155A and 156A may be arranged on a lower surface of the lower circuit layer 150AR, and the first and second lower memory regions 150AM1 and 150AM2 may be disposed on an upper surface of the lower circuit layer 150AR. The first and second lower memory regions 150AM1 and 150AM2 may be respectively connected to the plurality of lower chip pads 152A, 155A and 156A by interconnection circuits 116 of the lower circuit layer 150AR, and the first memory region 150AM1 may be disposed on the first channel region, and the second memory region 150AM2 may be disposed on the second channel region. The lower circuit layer 150AR may include interconnection patterns within the lower circuit layer 150AR and vias connecting the interconnection patterns.

The lower circuit layer 150AR may perform various operations according to the configuration. For example, the lower circuit layer 150AR may include a ground pattern, a power pattern, and a signal pattern. Here, the signal pattern may be defined as a transmission path of various signals, such as a data signal, excluding the ground pattern, the power pattern, and the like. The lower circuit layer 150AR may include a plurality of layers.

A plurality of lower chip pads 152A, 155A and 156A may be disposed below the lower circuit layer 150AR and may be electrically connected to the interconnection patterns. The plurality of lower chip pads 152A, 155A and 156A may be electrically connected to a plurality of first DQ connection pads 142A adjacent to each other in a third direction (Z-direction perpendicular to the upper surface of the package substrate 110). The plurality of lower chip pads 152A, 155A and 156A may include a plurality of lower data signal chip pads 152A connected to the plurality of first DQ connection pads 142A, and a plurality of lower power chip pads 156A connected to each of the plurality of power/ground connection pads 146. The lower DQ chip pads 152A electrically connected to the first data connection pads 142A in the third direction (Z-direction), perpendicular to the upper surface 110b of the package substrate, may be disposed on the first channel region CH1.

The plurality of lower chip pads 152A, 155A and 156A may include a conductive material, and may include, for example, aluminum (Al), gold (Au), cobalt (Co), copper (Cu), nickel (Ni), lead (Pb), tantalum (Ta), tellurium (Te), titanium (Ti), tungsten (W), or combinations thereof.

The lower insulating layer 150AD may be provided on and/or cover the plurality of lower chip pads 152A, 155A and 156A and the lower circuit layer 150AR. The lower insulating layer 150AD may be penetrated to expose the plurality of lower chip pads 152A, 155A and 156A electrically connected to interconnection patterns within the lower circuit layer 150AR. For example, at least a portion of each of the lower chip pads 152A of the first group may be exposed. According to another example, the lower insulating layer 150AD may extend by covering lower chip pads 152A of the second group spaced apart from the first group.

The lower insulating layer 150AD may include, for example, an insulating resin. The insulating resin may include a thermosetting resin such as, for example, an epoxy resin, a thermoplastic resin such as a polyimide, or a resin impregnated with an inorganic filler, such as prepreg, Ajinomoto Build-up Film (ABF), FR-4, or Bismaleimide-Triazine (BT). For example, the lower insulating layer 150AD may include a photosensitive resin such as photosensitive polyimide (PSPI).

An underfill resin 186 may fix the package substrate 110 and the first semiconductor chip 150A vertically stacked. The underfill resin 186 may be a capillary underfill (CUF), but may be a molded underfill (MUF) in one or more embodiments.

A plurality of conductive bumps 160 may be disposed between the first semiconductor chip 150A and the plurality of connection pads 140. The conductive bumps 160 may include connection bumps 160A, support bumps 160B and power bumps 160C.

The plurality of connection bumps 160A may electrically connect a plurality of first DQ connection pads 142A and a plurality of lower DQ chip pads 152A adjacent to each other in the third direction (Z-direction). For example, the plurality of connection bumps 160A may electrically connect the plurality of first lower DQ chip pads 152A and the plurality of first data connection pads 142A corresponding to each other. Accordingly, a data signal between the first data connection pad and the lower data chip pad may be transmitted.

Unlike the plurality of connection bumps 160A, the plurality of supporting bumps 160B may be spaced apart from each other by a plurality of dummy connecting pads 143, a plurality of lower DQ chip pads 152A and the lower insulating layer 150AD, which are adjacent to each other in the third direction (Z direction). The plurality of supporting bumps 160B may be disposed between the dummy connecting pads 143 and the lower insulating layer 150AD. The supporting bumps 160B may support the first semiconductor chip 150A, thereby preventing cracks that may occur in the connection bumps 160A of the first channel region CH1 due to tilting toward the second channel region CH2 or electrical short circuits between the first semiconductor chip 150A and the package substrate 110.

A plurality of conductive bumps 160 may include, for example, tin (Sn), indium (In), bismuth (Bi), antimony (Sb), copper (Cu), silver (Ag), zinc (Zn), lead (Pb), and/or alloys thereof. According to one or more embodiments, the plurality of conductive bumps 160 may have a form in which a conductive pillar and a solder ball are combined. For example, the conductive bumps 160 may include a solder ball 160S or a copper pillar 160P.

The first semiconductor chip 150A may be disposed on an upper surface of the package substrate 110 and may be electrically connected to a pad disposed on the upper surface of the package substrate 110. For example, the first semiconductor chip 150A may be mounted on the package substrate 110 in a flip-chip bonding manner through the conductive bumps 160P and 160S disposed on connection electrodes disposed on a lower surface of the first semiconductor chip (a lower surface of “150A” in FIG. 2). An underfill resin 186 including an epoxy resin or the like that is adjacent to and surrounds the plurality of conductive bumps 160 may be formed between a lower surface of the first semiconductor chip 150A and an upper surface of the package substrate 110.

The second semiconductor chip 150B may include a semiconductor base 150BB, an upper memory region 150BM, an upper circuit layer 150BR, a plurality of upper chip pads 152B, 155B and 156B, and an upper insulating layer 150BD.

The semiconductor base 150BB may be a semiconductor wafer substrate. For example, the semiconductor base 150BB may be a semiconductor wafer including a semiconductor element such as silicon and germanium, or a compound semiconductor such as silicon carbide (SiC), gallium arsenide (GaAs), indium arsenide (InAs), and indium phosphide (InP).

The upper memory region 150BM may include a first upper memory region 150BM1 and a second upper memory region 150BM2. The first and second upper memory regions 150BM1 and 150BM2 may include various types of material layers included in integrated circuits or memory components. The first and second upper memory regions 150BM1 and 150BM2 may be device layers including elements included in the integrated circuits or memory components. Electronic elements included in the memory component may be integrated in the first and second upper memory regions 150BM1 and 150BM2. The electronic elements may include transistor or capacitor structures.

The first upper memory region 150BM1 may be configured to transmit data through at least one channel. The second upper memory region 150BM2 may be configured to transmit data through at least one channel. For example, the first and second upper memory regions 150BM1 and 150BM2 may be configured to transmit data through one of the first channel and the second channel. For example, the first upper memory region 150BM1 may be connected to the first DQ connection pads 142A and may be configured to transmit and receive a data signal through the first channel, and the second upper memory region 150BM2 may be connected to the second DQ connection pad 142B and may be configured to transmit and receive a data signal through the second channel.

The memory region 150BM of the second semiconductor chip 150B may transmit data through at least one channel. However, embodiments are not limited thereto and, an entire memory region of a single semiconductor chip may be configured to transmit and receive a data signal of one channel. Accordingly, the data memory capacity per channel may be increased by allowing one semiconductor chip to transmit and receive data of only a single channel. Additionally, since one semiconductor chip does not transmit and receive two or more data signals, the DQ chip pads may be concentrated and disposed on one channel.

For example, according to one or more embodiments, the first upper memory region 150BM1 and the second upper memory region 150BM2 may be configured to transmit and receive data of the second channel through the upper DQ chip pads 152B. This may enable the second semiconductor chip 150B to transmit and receive only data of the second channel, thereby increasing the data transmission and reception capacity per semiconductor chip. Additionally, the second DQ chip pads 152B may be concentrated and disposed on the second channel region CH2. Accordingly, heat generation may occur on the second channel region CH2 rather than on an entire semiconductor chip.

On an upper surface of the upper circuit layer 150BR, a plurality of upper chip pads 152B, 155B and 156B may be arranged, and first and second upper memory regions 150BM1 and 150BM2 may be disposed on the upper surface of the upper circuit layer 150BR. The first and second upper memory regions 150BM1 and 150BM2 may be respectively connected to the plurality of upper chip pads 152B, 155B and 156B by the interconnection circuits 116 of the upper circuit layer 150BR, and the first memory region 150AM1 may be disposed on the first channel region, and the second memory region 150AM2 may be disposed on the second channel region.

The upper circuit layer 150BR may perform various operations depending on the configuration thereof. For example, the upper circuit layer 150BR may include a ground pattern, a power pattern, and a signal pattern. Here, the signal pattern may be defined as a transmission path of various signals, such as data signals, excluding the ground pattern, the power pattern, and the like. The upper circuit layer 150BR may include a plurality of layers.

A plurality of upper chip pads 152B, 155B and 156B may be disposed on the upper circuit layer 150BR and may be electrically connected to the interconnection patterns. The plurality of upper chip pads 152B, 155B and 156B may be electrically connected to the plurality of second DQ connection pads 142B on a second channel region CH2 adjacent to the first chip stack CS1. The plurality of upper chip pads 152B, 155B and 156B may include a plurality of upper data signal chip pads 152B connected to a plurality of second DQ connection pads 142B, and a plurality of upper power chip pads 156B connected to each of the plurality of power/ground connection pads 146. The upper DQ chip pads 152B electrically connected to the second DQ connection pads 142B in the third direction (Z-direction), perpendicular to the upper surface 110b of the package substrate 110, may be disposed on the second channel region CH2.

The plurality of upper chip pads 152B, 155B and 156B may include a conductive material, for example, aluminum (Al), gold (Au), cobalt (Co), copper (Cu), nickel (Ni), lead (Pb), tantalum (Ta), tellurium (Te), titanium (Ti), tungsten (W), or combinations thereof.

The upper insulating layer 150BD may be provided on and/or cover the plurality of upper chip pads 152B, 155B and 156B and the upper circuit layer 150BR. The upper insulating layer 150BD may be penetrated to expose the plurality of upper chip pads 152B, 155B and 156B electrically connected to the interconnection patterns within the upper circuit layer 150BR. For example, the upper insulating layer 150BD may extend by being provided on and/or covering the first group of lower chip pads 152B. As another example, at least portions of each of the upper chip pads 152B, 155B and 156B of the second group spaced apart from the first group may be exposed.

The upper insulating layer 150BD may include, for example, an insulating resin. The insulating resin may include a thermosetting resin such as, for example, an epoxy resin, a thermoplastic resin such as a polyimide, or a resin obtained by impregnating an inorganic filler to these resins, for example, a prepreg, Ajinomoto Build-up Film (ABF), FR-4, or Bismaleimide-Triazine (BT). For example, the upper insulating layer 150BD may include a photosensitive resin such as Photoimageable Dielectric (PID).

A plurality of bonding wires 170 may electrically connect a plurality of connection pads 142 and 146 on the upper surface of the package substrate 110 and a plurality of upper chip pads 152B, 155B and 156B on an upper surface of the second semiconductor chip 150B. The second semiconductor chip 150B may be mounted on an upper surface of the first semiconductor chip 150A and may have an upper surface on which the plurality of upper chip pads 152B are arranged. The plurality of upper chip pads 152B, 155B and 156B of the second semiconductor chip 150B may be electrically connected to the plurality of connection pads 140 of the package substrate 110 by the bonding wires 170. Accordingly, a data signal may be transmitted between the second data connection pad and the upper data chip pad.

The bonding wires 170 may be formed through a wire bonding process and may be conductive wires including conductive materials such as gold (Au) and copper (Cu).

The first semiconductor chip 150A and the second semiconductor chip 150B may be bonded and coupled to each other. The interchip bonding layer 185 may include a material that may be bonded and coupled to each other, for example, at least one of silicon oxide (SiO) and compounds thereof. In one or more embodiments, the interchip bonding layer 185 may include a film-shaped thermosetting resin or an ultraviolet-curable resin. For example, the interchip bonding layer 185 may include a resin film such as a die attach film (DAF).

The molding member 190 may be disposed on the upper surface 110b of the package substrate 110. The molding member 190 may be disposed on the upper surface 110b of the package substrate 110 so as to be provided on and/or cover the package substrate 110, the first chip stack CS1 of the first semiconductor chip 150A and the second semiconductor chip 150B on one region of the package substrate 110, the second chip stack CS of the third semiconductor chip 150C and the fourth semiconductor chip 150D on another region of the package substrate 110, and the first and second chip stacks CS1 and CS2 on the package substrate 110. The molding member 190 may be formed of resin. The molding member 190 may include, for example, epoxy mold compound (EMC).

Referring to FIG. 1A and FIG. 3, the first chip stack CS1 of the semiconductor package 100A may have the power/ground terminals 126 associated with power supply, the power/ground connection pads 146 connected to the power/ground terminals, the lower power chip pads 156A, the upper power chip pads 156B and the power bumps 160C.

The power/ground connection pads 146 respectively connected to the plurality of power/ground terminals 126 may be disposed on the package substrate 110. The plurality of power/ground connection pads 146 may be disposed to be located between the first chip stack CS1 and the package substrate 110. Additionally, the plurality of power/ground connection pads 146 may be disposed around the first chip stack CS1 to supply power to the second semiconductor chip 150B through wires. For example, the power/ground connection pads 146 may be disposed adjacently to the second semiconductor chip 150B in a region around one side of the first and second semiconductor chips 150A and 150B. The power/ground connection pads 146 may be disposed so as to be wire-bonded around a region in which the second semiconductor chip 150B is mounted.

In one or more embodiments, the power/ground connection pads 146 may be disposed over the entire upper surface of the package substrate 110, i.e., the first to fourth channel regions CH1, CH2, CH3 and CH4. Some of the power/ground connection pads 146 may be disposed within the mounting regions of the first and third semiconductor chips 150A and 150C, respectively, and may be connected to the first and third power chip pads 156A and 156C, respectively. Some power/ground connection pads 146 may be disposed within the mounting regions of the first and third semiconductor chips 150A and 150C, respectively, and may be connected to the first and third power/ground chip pads 156A and 156C, respectively.

The chip pads of the first and third semiconductor chips 150A and 150C, which are flip-chip bonded, may be connected to some power/ground connection pads 146 by conductive bumps 160, such as a micro bump.

The plurality of power bumps 160C may be disposed between the first semiconductor chip 150A and the plurality of connection pads 140.

The plurality of power bumps 160C may electrically connect a plurality of power/ground connection pads and a plurality of lower power chip pads adjacent to each other in the third direction (Z direction). For example, the plurality of power bumps 160C may electrically connect the plurality of power/ground connection pads 146 and the plurality of lower power chip pads 156A corresponding to each other. Accordingly, power may be transmitted between the power/ground connection pads 146 and the lower power chip pads 156A.

The plurality of lower power chip pads 156A may be disposed below the lower circuit layer 150AR, and may be electrically connected to the interconnection patterns. The plurality of lower power chip pads 156A may be electrically connected to the plurality of power/ground connection pads 146 adjacent to each other in the third direction (Z direction). The plurality of lower power chip pads 156A electrically connected to the plurality of power/ground connection pads 146 in the third direction (Z direction), perpendicular to the upper surface 110b of the package substrate, may be disposed over the first channel region CH1 and the second channel region CH2.

The plurality of lower power chip pads 156A may include a conductive material, for example, aluminum (Al), gold (Au), cobalt (Co), copper (Cu), nickel (Ni), lead (Pb), tantalum (Ta), tellurium (Te), titanium (Ti), tungsten (W), or combinations thereof.

The plurality of power bumps 160C may include, for example, tin (Sn), indium (In), bismuth (Bi), antimony (Sb), copper (Cu), silver (Ag), zinc (Zn), lead (Pb), and/or alloys thereof. According to one or more embodiments, the plurality of power bumps 160C may have a form in which a conductive pillar and a solder ball are combined. For example, the plurality of power bumps 160C may include a solder ball 160S or a copper pillar 160P.

A plurality of upper power chip pads 156B may be disposed on the upper circuit layer 150BR and may be electrically connected to the interconnection patterns. The plurality of upper power chip pads 156B may be electrically connected to the plurality of power/ground connection pads 146 on the second channel region CH2 adjacent to the first chip stack CS1. The plurality of upper power chip pads 156A electrically connected to the plurality of power/ground connection pads 146 may be disposed on the second channel region CH2 of the upper surface 110b of the package substrate.

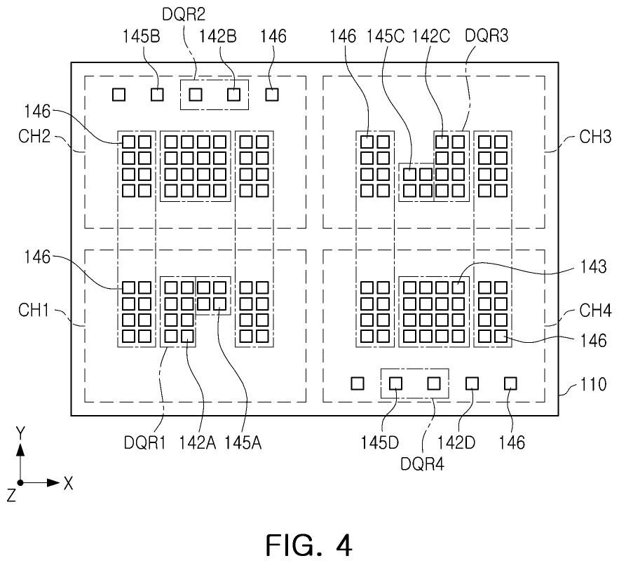

FIG. 4 is a plan view of a package substrate included in a semiconductor package according to one or more embodiments. FIG. 5A is a bottom view before a lower insulating layer of a semiconductor chip stack mounted on a semiconductor package according to one or more embodiments is disposed.

Referring to FIG. 4, first to fourth channel regions CH1, CH2, CH3 and CH4 and first to fourth data signal connection pad regions DQR1, DQR2, DQR3 and DQR4 may be disposed on an upper surface of a package substrate 110. Additionally, the first CA connection pad 145A, a second CA connection pad 145B, the third CA connection pad 145C, and a fourth CA connection pad 145D, dummy connection pads 143, and power/ground connection pads 146 may be disposed.

With respect to an arrangement region of DQ terminals 122 associated with data signals (DQ1, DQ2, DQ3 and DQ4 of FIG. 10A) of each channel may be divided into four channel regions CH1, CH2, CH3 and CH4 in a plane. For example, the first DQ connection pads 142A may be configured to transmit and receive a data signal through the first channel, and the second DQ connection pads 142B may be configured to transmit and receive a data signal through the second channel.

The first to fourth channel regions CH1, CH2, CH3 and CH4 may be provided as transmission paths for data signals (DQ1, DQ2, DQ3 and DQ4 of FIG. 10A) of the first to fourth channels respectively provided to the first to fourth semiconductor chips (150A, 150B, 150C and 150D of FIG. 1A). The first to fourth data signal regions DQR1, DQR2, DQR3 and DQR4 may include first to fourth data connection pads 142A, 142B, 142C and 142D connected to the data transmission paths.

The first data signal region DQR1 may be disposed between the first channel region CH1 and the first semiconductor chip 150A, and the second data signal region DQR2 may be disposed around the first semiconductor chip 150A.

The third data signal region DQR3 may be disposed between the third channel region CH3 and the third semiconductor chip 150C, and the fourth data signal region DQR4 may be arranged around the third semiconductor chip 150C.

A plurality of connection pads 140 respectively connected to the plurality of connection terminals (120 in FIG. 2) may be disposed on the package substrate 110. The plurality of connection pads 140 may include first to fourth DQ connection pads 142A, 142B, 142C and 142D respectively connected to the DQ terminals (122 of FIG. 2) of the first to fourth channels, first to fourth CA connection pads 145A, 145B, 145C and 145D respectively connected to the CA terminals (125 of FIG. 2) of the first to fourth channels, and power/ground connection pads 146 respectively connected to the power/ground terminals (126 of FIG. 2). The plurality of connection pads 140 may further include dummy connection pads 143 disposed within the second channel region CH2.

In one or more embodiments, the first to fourth DQ connection pads 142A, 142B, 142C and 142D may be disposed on the first to fourth channel regions CH1, CH2, CH3 and CH4, respectively.

The first and third CA connection pads 145A and 145C may be disposed within the mounting regions of the first and third semiconductor chips 150A and 150C, respectively, and may be connected to the first and third CA chip pads 155A and 155C, respectively. In one or more embodiments, the power/ground connection pads 146 may be disposed over the entire upper surface of the package substrate 110, i.e., the first to fourth channel regions CH1, CH2, CH3 and CH4, respectively.

Referring to FIGS. 4 and 5A, a power pattern region CPR may correspond to power/ground connection pads 146 disposed over the entire upper surface of the package substrate 110, i.e., the first to fourth channel regions CH1, CH2, CH3 and CH4, respectively. For example, the power pattern region CPR may have two straight portions along both side surfaces of a lower surface of the lower circuit layer 150AR. The power pattern region CPR may be disposed so as to vertically overlap a region on a substrate in which the power connection pads 146 of the substrate are disposed.

The data signal pattern region CDR and the control signal pattern region CCR may correspond to the first to fourth DQ connection pads 142A, 142B, 142C and 142D and the first to fourth CA connection pads 145A, 145B, 145C and 145D disposed on the first to fourth channel regions CH1, CH2, CH3 and CH4, respectively. For example, the data signal pattern region CDR and the control signal pattern region CCR may be disposed between the power pattern regions CPR disposed along both side surfaces of the lower surface of the lower circuit layer 150AR. The data signal pattern region CDR and the control signal pattern region CCR may be disposed so as to vertically overlap the region in which the first data signal region DQR1 and the first CA connection pads of the substrate are disposed on the substrate, respectively.

FIG. 5B is a bottom view of a semiconductor chip stack mounted on a semiconductor package according to one or more embodiments.

Referring to FIG. 5B, a plurality of lower chip pads 152A, 155A and 156A may be disposed below a lower circuit layer 150AR, and portions thereof may be exposed by a lower insulating layer 150AD. The exposed positions of the chip pads 152A may be electrically connected to interconnection patterns (115 of FIG. 2). The plurality of lower chip pads 152A, 155A and 156A may include a plurality of lower data signal chip pads 152A connected to the plurality of first DQ connection pads 142A, a plurality of first CA chip pads 155A connected to the plurality of first CA connection pads 145A, and a plurality of lower power chip pads 156A connected to each of the plurality of power/ground connection pads 146.

The plurality of lower power chip pads 156A may be disposed on two straight portions of the power pattern region CPR. The plurality of lower data signal chip pads 152A may be disposed in a data signal pattern region CDR between the power pattern regions CPR disposed along both side surfaces of the lower surface of the lower circuit layer 150AR. A plurality of first CA chip pads 155A may be disposed in the control signal pattern region CCR between the power pattern region CPR disposed along both side surfaces of the lower surface of the lower circuit layer 150AR.

FIG. 5C is a bottom view of a semiconductor chip stack mounted on a semiconductor package of one or more other embodiments.

Referring to FIG. 5C, a first semiconductor chip 150A′ may have a structure similar to that of the first semiconductor chip 150A illustrated in FIGS. 1 to 3, except that the power pattern region CPR is disposed adjacent to and to surround the data signal pattern region CDR and the control signal pattern region CCR. Accordingly, the description of the first semiconductor chip 150A illustrated in FIGS. 1 to 3 may be combined with the description of the first semiconductor chip 150A′ according to the embodiment of FIG. 5C unless otherwise specifically stated.

The power pattern region CPR may be disposed adjacent to and to surround the data signal pattern region CDR and the control signal pattern region CCR. For example, the power pattern region CPR may further have one straight portion and two extension portions extending along both edges of the first semiconductor chip 150A′ from both ends of the straight portion. The power pattern region CPR may have the straight portion so that the power pattern region CPR overlaps the second channel region CH2, thereby more efficiently transmitting and distributing the power inside the first semiconductor chip 150A′, to ensure stability and reliability of power supply, and minimize noise associated with power transmission.

FIG. 6A is a top view of a semiconductor chip stack mounted on a semiconductor package according to one or more embodiments before an upper insulating layer is disposed.

Referring to FIG. 6A, the power pattern region CPR may be disposed on the upper circuit layer 150BR disposed on the upper surface of the second semiconductor chip. For example, referring to FIG. 6A, the power pattern region CPR may have two straight portions along both side surfaces of the lower surface of the upper circuit layer 150BR.

Each of the data signal pattern region CDR and the control signal pattern region CCR may be disposed on the upper circuit layer 150BR disposed on the upper surface of the second semiconductor chip. For example, the data signal pattern region CDR and the control signal pattern region CCR may be disposed between the power pattern regions CPR disposed along both side surfaces of the upper surface of the upper circuit layer 150BR. The data signal pattern region CDR and the control signal pattern region CCR may vertically overlap the second channel region CH2, and may be disposed close to one side of the second semiconductor chip 150B adjacent to a region in which the second data signal region DQR2 of the substrate is disposed on the substrate.

FIG. 6B is a top view of a semiconductor chip stack mounted on a semiconductor package according to one or more embodiments.

Referring to FIG. 6B, a plurality of upper chip pads 152B, 155B and 156B may be disposed on the upper circuit layer 150BR, and portions thereof may be exposed by the upper insulating layer 150BD. The exposed portions of the chip pads 152A may be electrically connected to the bonding wire (170 of FIG. 1A). The plurality of upper chip pads 152B, 155B and 156B may include a plurality of upper data signal chip pads 152B connected to the plurality of second DQ connection pads (‘142B’ in FIG. 4), a plurality of second CA chip pads 155B connected to the plurality of second CA connection pads (‘145B’ in FIG. 4), and a plurality of upper power chip pads 156B connected to each of a plurality of power/ground connection pads (‘146’ in FIG. 4).

The plurality of upper power chip pads 156B may be disposed on two straight portions of the power pattern region CPR. The plurality of upper data signal chip pads 152B may be disposed in the data signal pattern region CDR between the power pattern regions CPR disposed along both side surfaces of the upper surface of the upper circuit layer 150BR. The plurality of second CA chip pads 155B may be disposed in the control signal pattern region CCR between the power pattern regions CPR disposed along both side surfaces of the upper surface of the upper circuit layer 150BR.

FIG. 6C is a top view of a semiconductor chip stack mounted on a semiconductor package according to one or more embodiments of modification.

Referring to FIG. 6C, a second semiconductor chip 150B′ according to one or more embodiments may have a similar structure to the second semiconductor chip 150B illustrated in FIGS. 1 to 3, except that the power pattern region CPR is disposed to surround the data signal pattern region CDR and the control signal pattern region CCR. Accordingly, the description of the second semiconductor chip 150B illustrated in FIGS. 1 to 3 may be combined with the description of the second semiconductor chip 150B′ according to the embodiment of FIG. 6C unless otherwise specifically stated.

The power pattern region CPR may be disposed adjacent to and to surround the data signal pattern region CDR and the control signal pattern region CCR. For example, the power pattern region CPR may further have one straight portion and two extensions extending from both ends of the straight portion along both edges of the second semiconductor chip 150B′. The power pattern region CPR may have the straight portion so that the power pattern region CPR overlaps the first channel region CH1, thereby more efficiently transmitting and distributing the power inside the second semiconductor chip 150Be, to ensure stability and reliability of power supply, and minimize noise associated with power transmission.

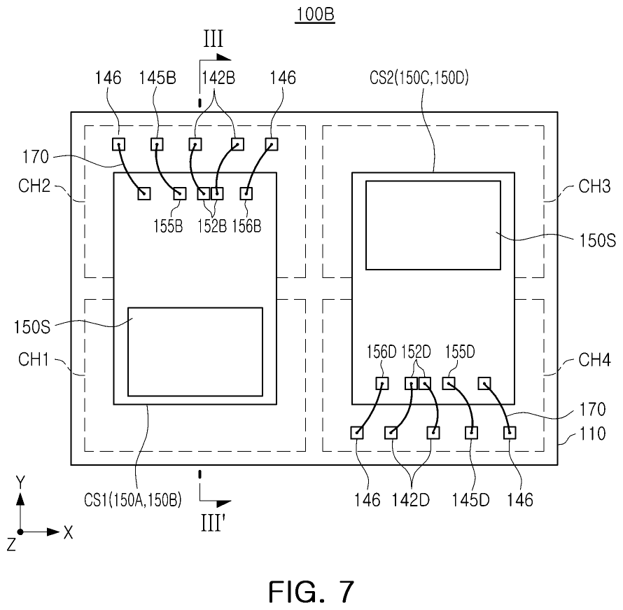

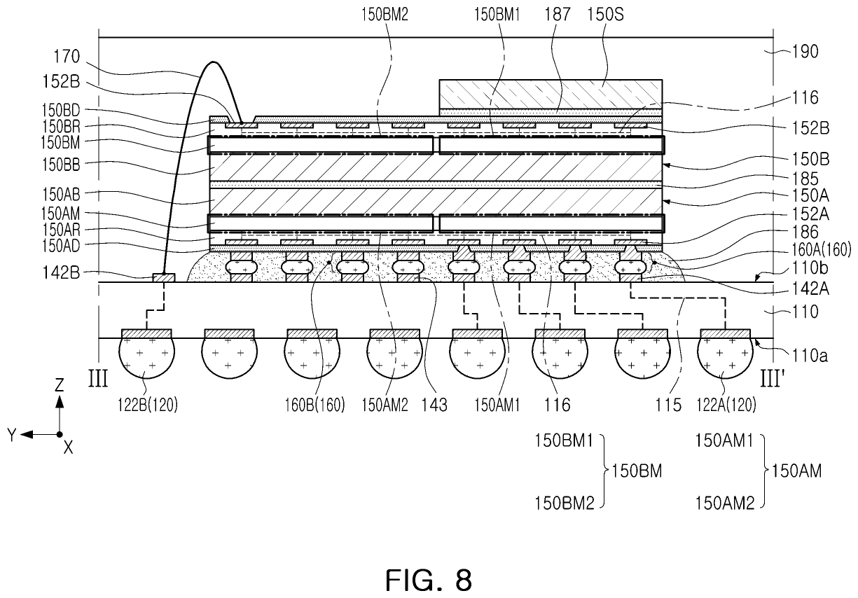

FIG. 7 is a plan view illustrating a semiconductor package according to one or more embodiments, and FIG. 8 is a cross-sectional view taken along line III-III′ of FIG. 7.

Referring to FIGS. 7 and 8, a semiconductor package 100B according to one or more embodiments may be understood as having a structure similar to the semiconductor package 100A illustrated in FIGS. 1 to 3, except that the semiconductor package 100B has further heat dissipation members (heat dissipators) on the first chip stack CS1 and the second chip stack CS2. Accordingly, the description of the semiconductor package 100A illustrated in FIGS. 1 to 3 may be combined with the description of the semiconductor package 100B according to the embodiment of FIGS. 7 and 8 unless otherwise specifically stated.

Heat dissipation members 150S may be disposed on the first chip stack CS1 and the second chip stack CS2. According to one or more embodiments, the chip stacks CS1 and CS2 having a lower chip of a flip chip bonding structure and an upper chip of a wire bonding structure may be configured, and semiconductor chips (150A, 150B and 150C, 150D) having the same structure may be alternately disposed in different chip stacks CS1 and CS2. Accordingly, since the first chip stack CS1 and the second chip stack CS2 may be configured identically, the following description will be made focusing on the components of the first chip stack CS1.

The heat dissipation member 150S may be disposed on at least a portion of the upper surface of the second semiconductor chip 150B in the first chip stack CS1. For example, the heat dissipation member 150S may overlap the first lower memory region 150AM1 and the first upper memory region 150BM1 in the third direction (Z-direction), perpendicular to the package substrate 110. According to one or more embodiments, heat generation may occur only in a specific region rather than the entire semiconductor chip. The heat generated when data is transmitted and received to the DQ chip pad 152A on the first channel region CH1 may transferred from the first lower memory region 150AM1 to the heat dissipation member 150S through the first upper memory region 150BM1 and may be released to the outside, thereby further improving the heat dissipation characteristics of the semiconductor chip.

The heat dissipation member 150S may include not only silicon (Si), but also metals such as gold (Au), silver (Ag) and copper (Cu), or conductive materials such as graphite and graphene.

The second semiconductor chip 100B and the heat dissipation member 150S may be bonded and coupled to each other. A heat dissipation member bonding layer 187 may include at least one of materials that may be bonded and coupled to each other, for example, at least one of silicon oxide (SiO) or compounds thereof.

In one or more embodiments, the heat dissipation member bonding layer 187 may include a thermosetting resin or an ultraviolet curable resin in a film form. For example, the heat dissipation member bonding layer 187 may include a resin film such as a die attach film (DAF).

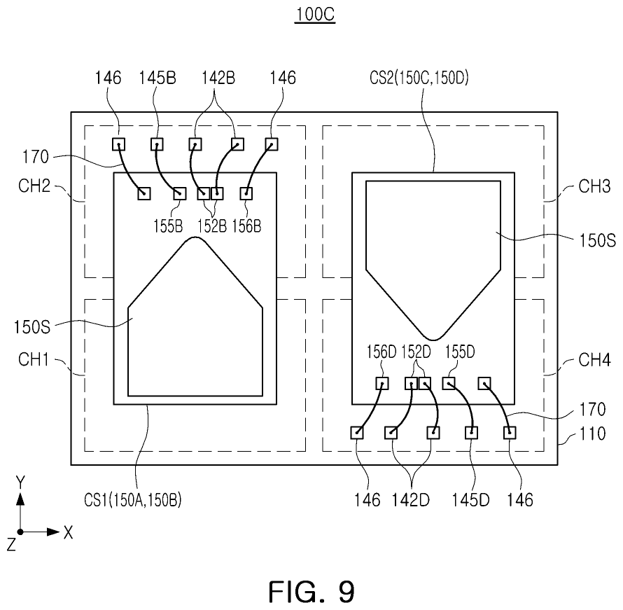

FIG. 9 is a plan view illustrating a semiconductor package of a modified embodiment.

Referring to FIG. 9, a semiconductor package 100C according to one or more embodiments may be understood as having a similar structure to the semiconductor package 100B illustrated in FIGS. 7 and 8, except that the heat dissipation members are widely disposed up to the second channel region CH2. Accordingly, the description of the semiconductor package 100B illustrated in FIGS. 7 and 8 may be combined with the description of the semiconductor package 100C according to the embodiment of FIG. 9 unless otherwise specifically stated.

For example, an area (e.g., a size) occupied by the heat dissipation member 150S may be about 50% or more of an area (e.g., a size) of an upper surface of the second semiconductor chip. In this case, the heat dissipation member 150S may be disposed on the first upper memory region 150BM1 and on the second upper memory region 150BM2. The upper chip pads may be disposed in a parallel manner along one edge of an upper surface of the second semiconductor chip 150B and may be exposed, and the heat dissipation member 150S may be disposed along a region excluding a region in which the upper chip pads 152B, 155B and 156B are exposed.

On a plane, the heat dissipation member 150S may have a shape in which a width thereof gradually increases from one side in which the exposed upper chip pads 152B, 155B and 156B are disposed, toward an opposite side of the heat dissipation member 150S. As a region in which the heat dissipation member 150S is disposed increases, the heat dissipation characteristics may be further improved. Accordingly, heat generated on the first channel region CH1 may be transferred and released to the outside through the heat dissipation member 150S, and furthermore, heat generated on the second channel region CH2 may be transferred and released through the heat dissipation member 150S, thereby more easily improving the heat dissipation characteristics of the semiconductor chip.

FIG. 10A is a plan view illustrating a semiconductor module according to one or more embodiments, and FIG. 10B is a portion of FIG. 10A, and is a plan view of a front surface of the semiconductor package.

Referring to FIG. 10A, a semiconductor module 200A may include a module substrate 210, a plurality of semiconductor packages 100A provided on the module substrate 210, and a connector 215 provided on one edge of an upper surface of the module substrate 210. Data signals DQ1, DQ2, DQ3 and DQ4 of the first to fourth channels may be transmitted between the semiconductor package 100A and the connector 215.

The semiconductor module 200A may include a memory module such as a DRAM module. For example, the semiconductor module 200A may include a plurality of semiconductor packages 100, and each of the plurality of semiconductor packages 100 may include two or more memory chips.

The semiconductor module 200A may further include a buffer chip 250 provided on the module substrate 210. The buffer chip 250 may buffer signals provided from an external device 300, such as a memory controller, for example, a command signal CMD, an address signal ADDR, and a control signal CTRL, and may provide these signals to the semiconductor package 100A. The external device 300 may control data reading from the semiconductor package 100 and data writing to the semiconductor package 100. The CA signals CA1, CA2, CA3 and CA4 of the first to fourth channels may be transmitted from the external device 300 or the buffer chip 250 to the semiconductor package 100A.

Referring to FIG. 10A, in one or more embodiments, the module substrate 210 may have a rectangular shape in which a length in the first direction (X-direction) is greater than a length in the second direction (Y-direction), intersecting therewith. The semiconductor packages 100 may be spaced apart from each other and arranged in the first direction (X-direction). The buffer chip 250 may be provided in a central portion of the upper surface of the module substrate 210 or a region adjacent thereto. Additionally, the connector 215 may include a plurality of pads in along the first direction (X-direction).

Referring to FIG. 10A and FIG. 10B, each of the plurality of semiconductor packages 100 may include a first chip stack of first and second semiconductor chips 150A and 150B and a second chip stack of third and fourth semiconductor chips 150C and 150D on a single package substrate 110, as described in FIGS. 1 to 4. The first and third semiconductor chips 150A and 150C may be provided as lower chips and may be flip-chip bonded to the package substrate 110. The second and fourth semiconductor chips 150B and 150D may be bonded to the package substrate 110 by the bonding wires 170.

As described in the previous example embodiment, paths through which the data signals DQ1, DQ2, DQ3 and DQ4 of the first channel to the fourth channel are provided may be configured in the first to fourth semiconductor chips 150A, 150B, 150C and 150D, respectively. Additionally, paths through which the CA signals CA1, CA2, CA3 and CA4 of the first channel to the fourth channel are provided may be configured in the first to fourth semiconductor chips 150A, 150B, 150C and 150D, respectively.

A structure implemented on the upper surface of the module substrate 210 may be implemented identically or similarly on a lower surface of the module substrate 210. In some example embodiments, the semiconductor module 200A may further include at least one semiconductor package provided on the lower surface of the module substrate 210, and optionally may further include a buffer chip 250.

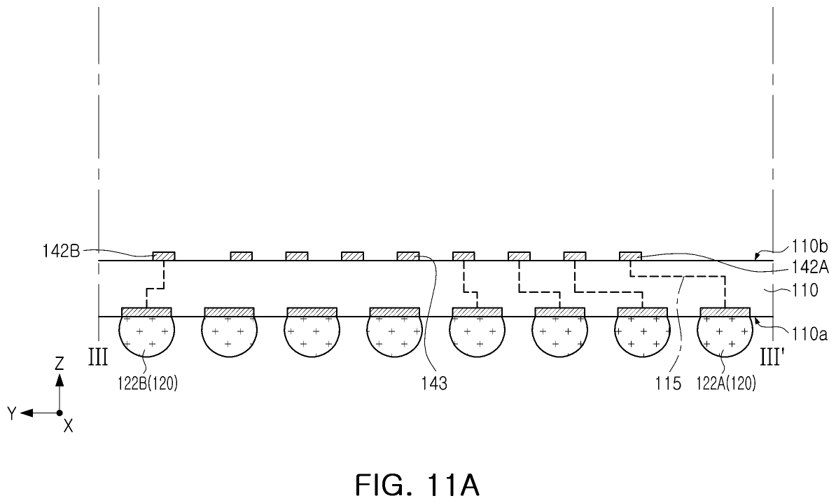

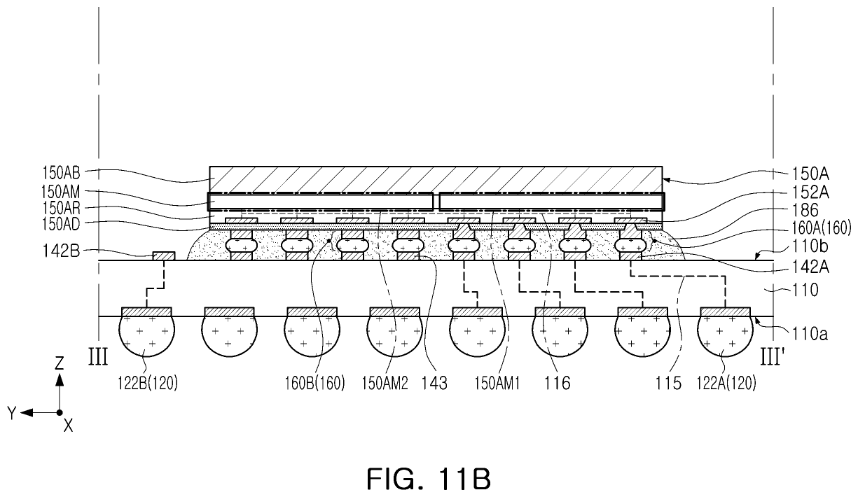

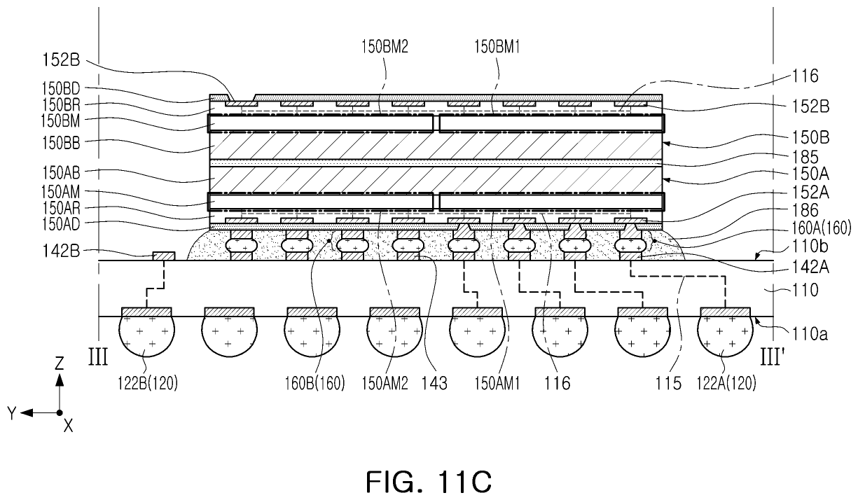

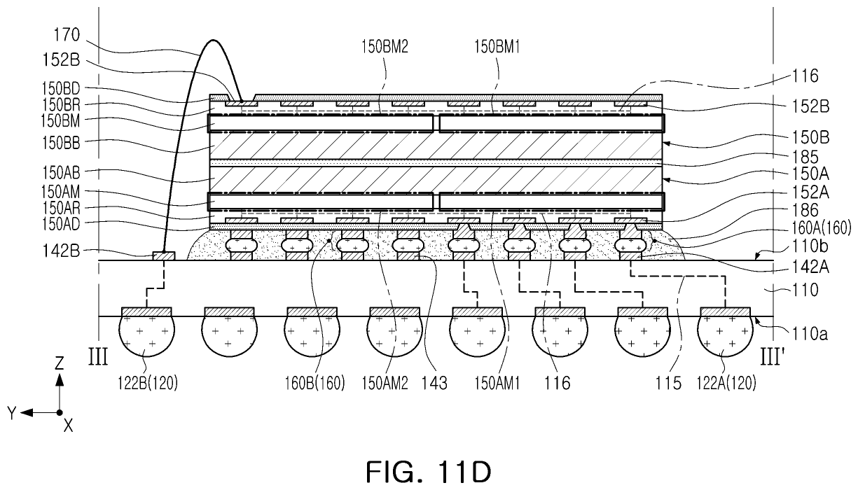

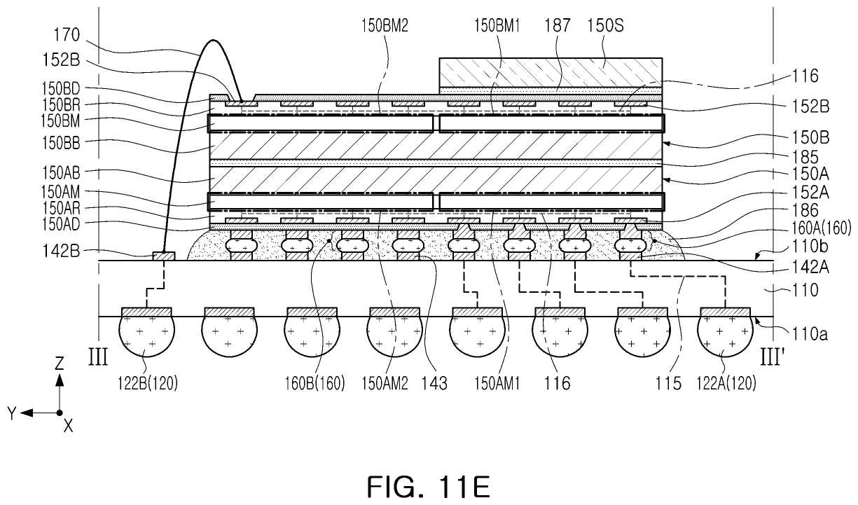

FIGS. 11A to 11E, FIGS. 1A and 7 are view illustrating a manufacturing process of a semiconductor package according to one or more embodiments. FIGS. 11A to 11D schematically illustrate a manufacturing process of a semiconductor package 100A of the embodiment illustrated in FIG. 1A. FIGS. 11A to 11E schematically illustrate a manufacturing process of a semiconductor package 100B of the embodiment illustrated in FIG. 7.

Referring to FIG. 11A, a plurality of connection terminals 120 may be arranged on the lower surface 110a of the package substrate 110, and a plurality of connection pads 140 may be arranged on the upper surface 110b of the package substrate 110. The plurality of connection pads 140 may be respectively connected to the plurality of connection terminals 120 by the interconnection circuits 115 of the package substrate 110, and may be respectively disposed in desired bonding regions for the first to fourth semiconductor chips 150A, 150B, 150C and 150D.

Referring to FIG. 11B, the first semiconductor chip 150A may be mounted on the upper surface of the package substrate 110. For example, the first semiconductor chip 150A may be mounted on the package substrate 110 in a flip-chip bonding manner, through the conductive bumps 160 disposed on connection electrodes disposed on the lower surface (a lower surface of 150A in FIG. 2) of the first semiconductor chip.

The plurality of conductive bumps 160 may be disposed between the first semiconductor chip 150A and the plurality of connection pads 140. The conductive bumps 160 may include connection bumps 160A, support bumps 160B, and power bumps 160C. In this case, the connection bumps 160A may be mounted so as to make contact on the first connection pads 142A. The support bumps 160B may be mounted so as to make contact on the dummy pads 143. The power bumps 160C may be mounted so as to make contact on power/ground pads 146.

An underfill resin 186 including an epoxy resin or the like that is adjacent to and surrounds the plurality of conductive bumps 160 may be formed between the lower surface of the first semiconductor chip 150A and the upper surface of the package substrate 110. The underfill resin 186 may fix the package substrate 110 and the first semiconductor chip 150A which are vertically stacked.

Referring to FIG. 11C, the second semiconductor chip 150B may be mounted on the upper surface of the first semiconductor chip 150A. In this case, the first semiconductor chip 150A and the second semiconductor chip 150B may be bonded and coupled to each other. The semiconductor base 150AB of the first semiconductor chip 100A and the semiconductor base 150BB of the second semiconductor chip 100B may be bonded to each other. Accordingly, the upper and lower memory regions 150AM1, 150AM2, 150BM1 and 150BM2 in which transistors, and the like, are disposed may be disposed to face opposite directions. Accordingly, the bonded portion and the upper and lower memory regions 150AM1, 150AM2, 150BM1 and 150BM2 may be disposed to be far apart from each other, which may assist in heat dissipation.

As the semiconductor base 150AB of the first semiconductor chip 100A and the semiconductor base 150BB of the second semiconductor chip 100B are bonded to each other, the interchip bonding layer 185 may include, for example, at least one of silicon oxide (SiO) and compounds thereof.

In one or more embodiments, the interchip bonding layer 185 may include a thermosetting resin or an ultraviolet-curable resin in the form of a film. For example, the interchip bonding layer 185 may include a resin film such as a die attach film (DAF). In this case, in a state in which the semiconductor base 150BB of the second semiconductor chip 100B and the die attach film are attached to each other, the semiconductor base 150BB of the second semiconductor chip 100B and the die attach film may be mounted on the semiconductor base 150AB of the first semiconductor chip 100A.

Referring to FIG. 11D, the plurality of upper chip pads 152B of the second semiconductor chip 150B may be electrically connected to the plurality of connection pads 140 of the package substrate 110 by the bonding wires 170. Accordingly, the plurality of connection pads 140 and the plurality of upper chip pads 152B, 155B and 156B may be electrically connected to each other. The bonding wires 170 may be formed in a wire bonding process.

In this case, referring further to FIG. 1A, the molding member 190 may be disposed on the upper surface 110b of the package substrate 110. The molding member 190 may be disposed on the upper surface 110b of the package substrate 110 to be provided on and/or cover the package substrate 110, the first chip stack CS1 of the first semiconductor chip 150A and the second semiconductor chip 150B on one region of the package substrate 110, the second chip stack CS of the third semiconductor chip 150C and the fourth semiconductor chip 150D on another region of the package substrate 110, and the first and second chip stacks CS1 and CS2 on the package substrate 110.

Referring to FIG. 11E, a heat dissipation member 150S may be disposed on at least a portion of the upper surface of a second semiconductor chip 150B in the first chip stack CS1. In this case, the heat dissipation member 150S and the second semiconductor chip 150B may be bonded and coupled to each other. For example, the heat dissipation member 150S and the upper insulating layer 150BD of the second semiconductor chip 100B may be bonded to each other. The heat dissipation member 150S may be disposed on the upper and lower memory regions 150AM1 and 150BM1 on the first channel region CH1. Accordingly, heat generated on the first channel region CH1 may be transferred and released to the outside through the heat dissipation member 150S, thereby easily improving the heat dissipation characteristics of the semiconductor chip.

As the heat dissipation member 150S of the first semiconductor chip 100A and the second semiconductor chip 150B are bonded to each other, the heat dissipation member bonding layer 187 may include materials that may be bonded and coupled to each other, for example, at least one of silicon oxide (SiO) or compounds thereof.

In one or more embodiments, the heat dissipation member bonding layer 187 may include a thermosetting resin or an ultraviolet curable resin in a film form. For example, the heat dissipation member bonding layer 187 may include a resin film such as a die attach film (DAF). In this case, in a state in which the heat dissipation member bonding layer 187 and the die attach film may be attached to each other, the heat dissipation member bonding layer 187 and the die attach film may be mounted on the upper insulating layer 150BD of the second semiconductor chip 100B.

In this case, referring further to FIG. 7, the molding member 190 may be disposed on the upper surface 110b of the package substrate 110. The molding member 190 may be disposed on the upper surface 110b of the package substrate 110 to be provided on and/or cover the package substrate 110, the first chip stack CS1 of the first semiconductor chip 150A and the second semiconductor chip 150B on one region of the package substrate 110, the second chip stack CS of the third semiconductor chip 150C and the fourth semiconductor chip 150D on another region of the package substrate 110, and the heat dissipation members 150S of the package substrate 110, and the first and second chip stacks CS1 and CS2 and the heat dissipation members 150S on the package substrate 110.

According to still another aspect of one or more embodiments, there is provided a manufacturing method of a semiconductor package, the method including forming a package substrate, forming a plurality of connection pads on a first surface of the package substrate, the plurality of connection pads including a first connection pad and a second connection pad, forming a first semiconductor chip on the plurality of connection pads, the first semiconductor chip, forming a second semiconductor chip on the first semiconductor chip, forming an interchip bonding layer between the first semiconductor chip and the second semiconductor chip, forming a connection bump connecting the first connection pad and a lower chip pad included in the first semiconductor chip, and forming a bonding wire connecting the second connection pad and an upper chip pad included in the second semiconductor chip.

Forming the first semiconductor chip may include forming lower chip pads including a first group on a second surface of the first semiconductor chip and a second group spaced apart from the first group, and forming a lower insulating layer extending on a lower chip pad included in the second group and exposing at least a portion of a lower chip pad included in the first group.

Forming the second semiconductor chip may include forming upper chip pads including a first group on a first surface of the second semiconductor chip and a second group spaced apart from the first group, and forming a first insulating layer extending on an upper chip pad included in the first group and exposing at least a portion of an upper chip pad included in the second group.

The method may further include forming a heat dissipator on at least a portion of the upper insulating layer, and the heat dissipator may overlap the upper chip pad included in the first group.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package, comprising:
a package substrate;
a plurality of connection pads on a first surface of the package substrate, the plurality of connection pads comprising a first connection pad and a second connection pad;
a first semiconductor chip on the plurality of connection pads, the first semiconductor chip comprising:
lower chip pads comprising a first group on a second surface of the first semiconductor chip and a second group spaced apart from the first group; and
a lower insulating layer extending on a lower chip pad included in the second group and exposing at least a portion of a lower chip pad included in the first group;
a second semiconductor chip on the first semiconductor chip, the second semiconductor chip comprising:
upper chip pads comprising a first group on a first surface of the second semiconductor chip and a second group spaced apart from the first group; and
an upper insulating layer extending on an upper chip pad included in the first group and exposing at least a portion of an upper chip pad included in the second group;
an interchip bonding layer between the first semiconductor chip and the second semiconductor chip;
a connection bump connecting the first connection pad and the lower chip pad included in the first group; and
a bonding wire connecting the second connection pad and the upper chip pad included in the second group.

2. The semiconductor package of claim 1, wherein the package substrate comprises a first channel region and a second channel region, the first connection pad being on the first channel region and the second connection pad being on the second channel region, and
wherein the lower chip pad included in the first group electrically connected to the first connection pad in a first direction, perpendicular to the first surface of the package substrate, is on the first channel region.

3. The semiconductor package of claim 2, wherein the upper chip pad included in the second group is on the second channel region in the first direction.

4. The semiconductor package of claim 2, wherein the plurality of connection pads further comprise a dummy connection pad on the second channel region, and
wherein the semiconductor package further comprises a support bump between the dummy connection pad and the lower insulating layer, the support bump being configured to support the first semiconductor chip.

5. The semiconductor package of claim 4, wherein the lower insulating layer is between the lower chip pad included in the second group and the support bump.

6. The semiconductor package of claim 1, wherein each of the connection bump further comprises a pillar portion in contact with the lower chip pad included in the first group and a solder portion on the pillar portion.

7. The semiconductor package of claim 1, wherein the upper chip pad included in the second group is parallel to a first edge of the first surface of the second semiconductor chip.

8. The semiconductor package of claim 1, wherein the semiconductor package further comprises a heat dissipator on at least a portion of the upper insulating layer, and
wherein the heat dissipator overlaps the upper chip pad included in the first group.

9. The semiconductor package of claim 8, wherein a region occupied by the heat dissipator is equal to or greater than 50% of an area of the first surface of the second semiconductor chip.

10. The semiconductor package of claim 8, wherein the upper chip pad included in the second group is parallel to a first edge of the first surface of the second semiconductor chip, and
wherein, in a plane, the heat dissipator has a shape in which a width gradually increases in a direction from a first edge of the heat dissipator in which the upper chip pad included in the second group is disposed, toward a second edge of the heat dissipator opposite to the first edge of the heat dissipator.

11. The semiconductor package of claim 8, wherein the heat dissipator comprises silicon (Si) or compounds thereof.

12. A semiconductor package, comprising:
a package substrate;
a plurality of connection pads on a first surface of the package substrate, the plurality of connection pads comprising a first connection pad and a second connection pad;
a first semiconductor chip on the plurality of connection pads, the first semiconductor chip comprising a first lower memory region configured to transmit data through at least one of a first channel and a second channel, and a second lower memory region configured to transmit data through at least one of the first channel and the second channel;
a second semiconductor chip on the first semiconductor chip, the second semiconductor chip comprising a first upper memory region configured to transmit data through at least one of the first channel and the second channel, and a second upper memory region configured to transmit data through at least one of the first channel and the second channel;
a connection bump connecting the first lower memory region and the second lower memory region to the first connection pad; and
a bonding wire connecting the first upper memory region and the second upper memory region to the second connection pad.

13. The semiconductor package of claim 12, wherein the package substrate comprises a first channel region and a second channel region parallel to the first channel region, and
wherein an area of a region of the first channel region overlapping with the first semiconductor chip is the same as an area of a region of the second channel region overlapping the first semiconductor chip.

14. The semiconductor package of claim 12, wherein the first semiconductor chip further comprises interconnection circuits on the first lower memory region and the second lower memory region, and
wherein the interconnection circuits electrically connect the first lower memory region and the second lower memory region to the connection bump.

15. The semiconductor package of claim 12, wherein the first semiconductor chip further comprises a lower chip pad connected to the first connection pad, and
wherein the lower chip pad on the first lower memory region is connected to the connection bump, and the lower chip pad on the second lower memory region is spaced apart from the connection bump.

16. The semiconductor package of claim 12, wherein the second semiconductor chip further comprises a first chip pad connected to the second connection pad, and
wherein an upper chip pad on the second upper memory region is connected to the bonding wire, and the upper chip pad on the first upper memory region is spaced apart from the bonding wire.

17. The semiconductor package of claim 12, wherein the connection bump overlaps the first lower memory region and the first upper memory region, and
wherein the bonding wire overlaps the second lower memory region and the second upper memory region.

18. A semiconductor package, comprising:
a package substrate comprising a first transmission path and a second transmission path;
a first channel region on a first surface of the package substrate and connected to the first transmission path;
a second channel region parallel to the first channel region and connected to the second transmission path;
a first semiconductor chip comprising a first lower memory region and a second lower memory region, over the first semiconductor chip being on a portion of the first channel region and a portion of the second channel region;
a second semiconductor chip comprising a first upper memory region and a second upper memory region, the second semiconductor chip on the first semiconductor chip;
a connection bump connecting the first transmission path to the first lower memory region and the second lower memory region; and
a bonding wire connecting the second transmission path to the first upper memory region and the second upper memory region.

19. The semiconductor package of claim 18, wherein a region on the package substrate in which the bonding wire is disposed is closer to an edge of the package substrate than a region on the package substrate in which the connection bump is disposed.

20. The semiconductor package of claim 18, wherein the package substrate further comprises a connection terminals on a second surface of the package substrate opposite to the first surface of the package substrate, and
wherein the connection terminals are in a two-dimensional array in a second direction and a third direction that is perpendicular to the second direction.
